(19) United States
(12) Patent Application Publication
(10) Pub. No.: US 2023/0318520 A1
(43) Pub. Date: Oct. 5, 2023

(54) FRAMEWORK FOR DEPLOYABLE SOLAR PANELS THAT CAN BE ARRANGED ABOVE A CONTAINER-TYPE MODULAR ELEMENT

(71) Applicant: ECOSUN INNOVATIONS, Hombourg (FR)

(72) Inventors: Jean-Michel FUCHS, Volgelsheim (FR); Frédéric ROHMER, Ebersheim (FR)

(73) Assignee: ECOSUN INNOVATIONS, Hombourg (FR)

(21) Appl. No.: 18/013,503

(22) PCT Filed: Jul. 5, 2021
(86) PCT No.: PCT/EP2021/068557

§ 371 Date: Dec. 28, 2022

(30) Foreign Application Priority Data
Jul. 6, 2020 (FR) FR2007126

(51) Int. Cl. H02S 20/30

(52) U.S. Cl. CPC H02S 20/30

(57) ABSTRACT

A framework for deployable solar panels that can be arranged above a container comprises a rectangular housing and lower movable frames. The framework also comprises upper movable frames arranged above the lower movable frames. The movable frames are suitable for each receiving an associated deployable solar panel. In the non-deployed position of the solar panels, the movable frames are fully contained inside the housing in respective planes one above the other. In the deployed position of the solar panels, the upper and lower movable frames are substantially in the same plane side by side, with the lower movable frame extending outwards beyond the transverse or longitudinal limits of the housing and passing between respective stacked beams of the lower frame and the upper frame of the housing.

### TECHNICAL FIELD

The present invention relates to a framework for deployable solar panels, that can be arranged above a container-type modular element.

The invention has applications, in particular, in the field of modular construction, or container construction, in particular for modular housing, modular storage shelters or other, and technical Shelters.

### PRIOR ART

Container construction is suitable for numerous applications, both civil (for example, for industry, commercial, tertiary, collective or individual rental investment) and military. The modular architecture makes it possible to construct buildings that are optionally dismountable, from easily transportable modular elements (or modules).

In the state of the art, for example, the following are thus known, in a non-limiting manner:
construction containers;
sanitary cabins;
sustainable and definitive modular buildings (which can be compliant with RT2012);
provisional site facility or construction camp buildings;
dismountable, transportable and reusable kit buildings;
technical Shelters;
etc.

Modular elements such as those listed above can be produced on the same constructive base as shipping containers and adopt their standard dimensions with the advantage of thus being able to be transported and manoeuvred with the same vehicles (forklift trucks, cranes, container trucks, railway carriages, etc.). However, given that they are not subjected to the constraints of sea transport, they do not need any CSC approval (sea approval). Due to this, they are inexpensive and lighter than the sea version.

A technical Shelter is a protective casing for technical equipment. It serves as a transportable technical room, to hold equipment under optical conditions of use and to preserve it from external or climatic aggressions (temperature, humidity, air, dust, hydrometry, intrusion, etc.) on a site of use.

In the military field, a Shelter can contain an electrical energy production unit by encapsulating, for example, a power generator, but can also form a modular data centre, a radio-communications control unit, a mobile command centre, an equipment, weapons storage unit, etc.

It is known to equip a modular element of the abovementioned type of a photovoltaic system designed to make an electrical installation contained in the container operate autonomously, by generating electrical energy from solar energy with the possibility of recharging batteries. To this end, solar panels can be fixedly connected, by screwing, to the roof or on a framework inclined with respect to the horizontal of an angle of between 0 and 90°, usually between 3 and 10°.

For example, document CN 209568746 U discloses a photovoltaic energy storage container, having a container body and a solar panel support mounted on the upper side of the container body, in order to support a solar panel with a certain inclination with respect to the horizontal. A scaling ladder is installed at the end of the container body to enable a worker to climb above the container, in order to ensure the maintenance and the replacement of the solar panel.

In a certain number of applications, it is desirable to provide enough solar energy to power an electrical installation contained in the container, which can require more than one solar panel.

Document EP 2822178 A1 discloses a movable solar island installation, comprising a plurality of flat photovoltaic solar modules, an energy store, and a charge regulator connected to the solar modules and to the energy store. The movable solar island installation is integrated in a container comprising two longitudinal walls, two transverse walls, a bottom and an upper side. This is, in particular, an ISO container, wherein the charge regulator and the energy store are also provided, in particular in a fixedly installed form. The container, as well as at least some of the solar modules are designed such that the solar modules can be stored inside the container for the transport of the solar island installation, and be arranged outside of the container during the operation of the solar island installation. At least one transverse wall of the container is provided with at least one vertically oriented extension, extractible from this transverse wall of the container, some of the solar modules of the solar island installation being arranged in this extension.

In this prior art, however, the container is itself provided to contain the electrical energy generation unit. All or some of the internal space of the container is therefore occupied by the solar modules during transport, and is not therefore available for another use. In other words, the container is used to ensure a function of protective means and transporting solar panels of the solar island installation.

The invention conversely aims to make it possible to provide a container which ensures another function, or indirect function, for example a habitable module or technical Shelter function, of a set of solar panels capable of producing enough photovoltaic energy to generate the power supply necessary for said indirect function.

### SUMMARY OF THE INVENTION

The invention aims to propose a solution making it possible, in particular, to improve the prior art that complies with document CN 209568746 U, in order to make it possible to produce more photovoltaic energy by increasing the number of solar panels used, without penalising the space inside the container.

This aim is achieved, thanks to a framework according to claim 1. The invention relates to a framework (100) for deployable solar panels that can be arranged above a container-type modular element, comprising a substantially rectangular housing, wherein: the rectangular housing has a lower frame (110) and an upper frame (120) of substantially identical rectangular shapes, which are stacked edge-to-edge by being spaced apart vertically from one another by spacers (130) of determined height; the lower frame comprises four bottom corner parts (111-114) and the upper frame comprising four top corner parts (121-124), which are stacked two-by-two; each of the lower and upper frames comprises a pair of longitudinal beams and a pair of transverse beams which are stacked two-by-two, said pairs of beams each connecting two-by-two, the four bottom corner parts and the four top corner parts, respectively: the framework further comprises at least one first lower movable frame (211a, 211b, 211c) and at least one upper movable frame (221a, 221b, 221c) which are suitable for each receiving an associated deployable solar panel, and which are arranged such that they are, in the non-deployed position of the associated solar panels, fully contained inside the rectangular housing in respective planes one above the other, and are, in the deployed position of the associated solar panels, substantially in the same plane side by side with the lower movable frame extending at least partially outwards beyond the transverse or longitudinal limits of the housing, passing between two respective stacked beams of the lower frame (110) and of the upper frame (120) of said housing, namely between a beam of one of the pairs of transverse beams of the lower frame and a beam of one of the pairs of transverse beams of the upper frame, or between a beam of one of the pairs of longitudinal beams of the lower frame and a beam of one of the pairs of longitudinal beams of the upper frame, respectively.

Advantageously, such a framework is transportable independently from the container itself. It can therefore be installed on a container afterwards, i.e. after manufacture, transport and installation of the container on its operating site.

Furthermore, due to its design from corner parts which comply with the specifications of the standard ISO 1161-1984 of ISO, the framework can be arranged on an ISO container in the same way as if this were for another ISO container. The framework does not therefore require handling means, nor specific fixing means to be arranged above an ISO container. For the same reason, frameworks which comply with the invention can be piled (stacked) and fixed to one another, thanks to the same fixing means as those which are used for fixing stacked ISO containers, for their transport by sea on a cargo ship, for example.

The frameworks are transportable and can be handled like a container by standard container lifting means.

Embodiments, taken individually or in combination, further provide that in the framework according to the invention, corner parts are container corner parts which comply with the standard ISO 1161-1984. In a preferred embodiment of the invention, the overall height of the framework, in the non-deployed position of the lower movable frame and of the lower movable frame is at most, equal to 1 foot, that is about 30 centimetres.

In another preferred embodiment of the invention, the framework further comprises hinges (250) arranged at a longitudinal beam or at a transverse beam of the upper frame (120) of the housing, coupling the upper movable frame to said upper frame of the housing, such that said upper movable frame can pivot around said hinges during the deployment of the associated solar panel, in order to be inclined, with a first slope determined with respect to the plane of the framework, outwards beyond the transverse or longitudinal limits of the housing. In another preferred embodiment of the invention, the upper movable frame does not pivot around said hinges during the deployment of the associated solar panel and remains in the non-deployed and fixed position.

According to another preferred embodiment of the invention, the framework comprises mutual blocking means suitable for maintaining between them two upper movable frames in the deployed position of the associated solar panels, each in the inclined position with a slope of determined value.

In another preferred embodiment of the invention, the framework further comprises slides (150, 170a, 170b) which extend perpendicularly to the respective stacked beams of the lower frame (110) and of the upper frame (120) of the housing (110, 120) between which the first lower movable frame can extend outwards beyond the transverse or longitudinal limits of the housing, to slidingly guide said movable frame along the transverse direction (Y) or the longitudinal direction (X), respectively.

According to another preferred embodiment of the invention, the first lower movable frame and the slide are arranged such that said first lower frame can slide in the slide outwards from the housing with capacity to incline, at least at the end of travel, downwards with respect to the longitudinal axis of said slide, so as to have a second determined slope, with respect to the plane of the framework, in the deployed position of the associated solar panel.

In another preferred embodiment of the invention, the lower movable frame (200, 300) comprises at least one restraining wedge (206, 306) suitable for engaging with an abutment (106) of the housing to restrain the movable frame such that it does not escape fully from the housing (110, 120) in the fully deployed position of the associated solar panel.

According to another preferred embodiment of the invention, the framework comprises two rows of adjacent lower movable frames (211a, 211b, 211c) two-by-two in the longitudinal direction (X) of the lower frame (110) of the framework, at a rate of one row on either side, respectively, of a median of said lower frame of the framework that extends in said longitudinal direction, and two rows of adjacent upper movable frames (221a, 221b, 221c) two-by-two in the longitudinal direction of the upper frame (120) of the framework, at a rate of one row on either side, respectively, of a median of said upper frame of the framework that extends in said longitudinal direction.

In another preferred embodiment of the invention, the framework comprises two rows of pairs of adjacent lower movable frames (311a-311c, 331a-331c) two-by-two in the longitudinal direction (X) of the lower frame (110) of the framework, said pairs of movable frames being fully contained, in the non-deployed position of the associated solar panels, inside the rectangular housing in respective planes one above the other, and that extend, in the deployment position of the associated solar panels, at least partially outwards beyond the transverse or longitudinal limits of the housing, passing between respective stacked beams of the lower frame (110) and of the upper frame (120) of said housing, each on a respective transverse or longitudinal side of said housing; and two rows of adjacent upper movable frames (221a, 221b, 221c) two-by-two in the longitudinal direction of the upper frame (120) of the framework, at a rate of one row on either side, respectively, of a median of said upper frame of the framework that extends in said longitudinal direction.

### BRIEF DESCRIPTION OF THE DRAWINGS

Other features and advantages of the invention will also appear upon reading the description below. This is purely illustrative and must be read regarding the accompanying drawings, wherein:

FIG. 1 is a schematic, three-dimensional representation of an ISO container as an example of a modular element, with which embodiments of the framework according to the invention can be used;

FIG. 2 is a three-dimensional view of corner parts contributing to the construction of the container of [FIG. 1] and of the framework according to the embodiments;

FIG. 3 is a simplified, schematic, three-dimensional representation of a framework according to the embodiments of the invention arranged on an ISO container, like the container of [FIG. 1];

FIG. 4 is a three-dimensional view of a framework according to the embodiments of the invention with twelve solar panels in the deployed position;

FIG. 5 is a three-dimensional, three-quarter view of the framework of [FIG. 4];

FIG. 6 is a top view of the framework of [FIG. 4] and of [FIG. 5];

FIG. 7 is a side view, along the cross-section A-A of [FIG. 6] of the framework of FIGS. 4, 5 and 6;

FIG. 8 is a cross-sectional view, along the cross-section B-B of [FIG. 6] of a portion of the framework of FIGS. 4, 5 and 6;

FIG. 9 is a cross-sectional view, along the cross-section C-C of [FIG. 6] of another portion of the framework of FIGS. 4, 5 and 6;

FIG. 10 is a side view of a movable frame associated with a solar panel, of a framework according to the embodiments of the invention;

FIG. 11 is a side view of the framework of FIGS. 4, 5 and 6;

FIG. 12 shows an embodiment of a lower movable frame 300, associated with a pair of lower solar panels, like the pairs 311a-311c and the pairs 331a-331c of [FIG. 11];

FIG. 13 is a side view of an assembly of two lower movable frames arranged in a two-stage slide, for a version of the framework with eighteen solar panels, for example, instead of the framework with twelve solar panels of FIGS. 4, 5 and 6;

FIG. 14 is a side view, similar to that of [FIG. 11], but for a framework with eighteen solar panels instead of the framework with twelve solar panels;

FIG. 15 is a side, cross-sectional view, along the cross-section B-B of said figure;

FIG. 16 is a front view showing the left-hand lateral side of the framework 100 according to the second embodiment with the housing 110, 120 of [FIG. 13] equipped with movable frames for the lower and upper solar panels shown in [FIG. 12];

FIG. 17 is a cross-sectional view of the framework 100 of [FIG. 16], along the cross-section C-C of said figure.

### DETAILED DESCRIPTION OF EMBODIMENTS

In the description of embodiments below and in the Figures of the accompanying drawings, the same elements or similar elements have the same numerical references in the drawings.

The embodiments of a framework for deployable solar panels which will be described, are particularly suitable for the mounting on modular elements of the container type, intended for housing (also called, “module housing”), for example for the construction of dwellings, offices, site facilities, etc. However, a person skilled in the art will assess that the embodiments described in the present description are also suitable for the mounting of frameworks on any other type of modular element, like 10, 20, 30 or 40-foot shipping containers, storage containers, refrigerated containers, sanitary cabins, technical Shelters, for civil or military application, etc.

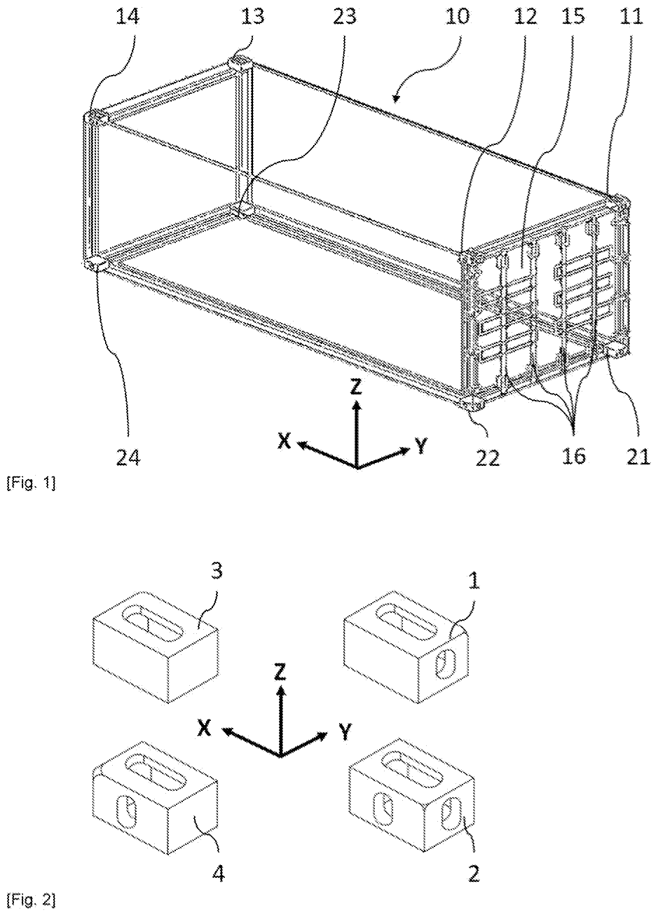

In reference to the diagram of [FIG. 1], a container 10, like a 20-foot ISO shipping container such as represented, has a mainly rectangular shape, with four large sides (two substantially horizontal sides, including a floor (i.e. a bottom side), generally covered with a 28 mm-thick plywood floor, for example, and a roof (i.e. a top side), as well as two large vertical walls) longitudinally extending, and with two small transversally extending walls. One of the small sides, conventionally called the front side 15, is made of a double door equipped with closing bars 16, for example made of galvanised steel, for the loading and unloading of goods in the container 10.

The orthogonal marker at the bottom of the figure indicates the longitudinal direction X of the container oriented from the front side 15 towards the bottom of said container, i.e. towards the small side opposite the front side 15 which is equipped with the double door, the transverse direction Y of the container, which is orthogonal to said direction X and conventionally oriented from the left to the right, and the vertical direction Z (direction of gravity) conventionally oriented from the bottom to the top. Below, and except expressly mentioned otherwise:
the expressions “length”, “axial”, “front” or “rear”, “frontwards”, “rearwards”, and “in front” or “at the rear” will be used in reference to the observation in the direction of the longitudinal axis X;
the expressions “width”, “lateral”, “right” or “left”, “to the right” or “to the left”, and “by the right” or “by the left” will be used in reference to the observation in the direction of the transverse axis X;
the expressions “height”, “on top” or “under”, “above” or “below”, and “over” or “underneath”, “bottom” and “top”, “at the bottom” and “at the top”, “lower” and “upper”, will be used in reference to the observation in the direction of the vertical axis Z.

Such containers are generally of standardised dimensions according to the standard ISO 668-1995 of ISO (International Organization for Standardization) and to its amendments. Thus, for example:
their length L in the longitudinal direction X is equal to 2.991 metres (m), or to 6.058 m, or also to 9.144 m or to 12.192 m (for 10, 20, 30 and 40-foot containers, respectively);
their width I in the transverse direction Y is 2.438 m (that is 8 feet) to be compatible with the regulations relating to road transport, on container trucks; and,
their height H in the vertical direction Z is 2.591 m (that is 8.5 feet), or 2.896 m (that is 9.5 feet) for what is called a “high cube” (or HC) container.

With dimensions thus standardised, ISO containers are easy to handle with a forklift, a crane or a quay crane, to store, if necessary, by stacking them generally on at least six levels, and to transport by boats, by train, or by carrier trucks.

Such a container 10 is made from profiled steel parts, which are welded together with corner parts. More specifically, the containers are assembled by welding on eight corner parts which are moulded steel parts, with shape and dimensions standardised according to the standard ISO 1161-1984. Their dimensions are 178 millimetres (mm) long (in the longitudinal direction X) by 162 mm wide (in the transverse direction Y) and by 118 mm high (in the vertical direction Z). Such a corner part is also called corner.

[FIG. 2] shows four corner parts 1, 2, 3 and 4 which can be used to form the four corners of the top side (or roof) of the container 10 of [FIG. 1], namely the front-right corner 11, the front-left corner 12, the rear-right corner 13 and the rear-left corner 14, respectively. Corner parts which are identical to the parts 1 to 4 are also used, but vice versa, to form the four corners of the bottom side (or floor) of the container 10, namely the front-right corner 21, the front-left corner 22, the rear-right corner 23 and the rear-left corner 24, respectively.

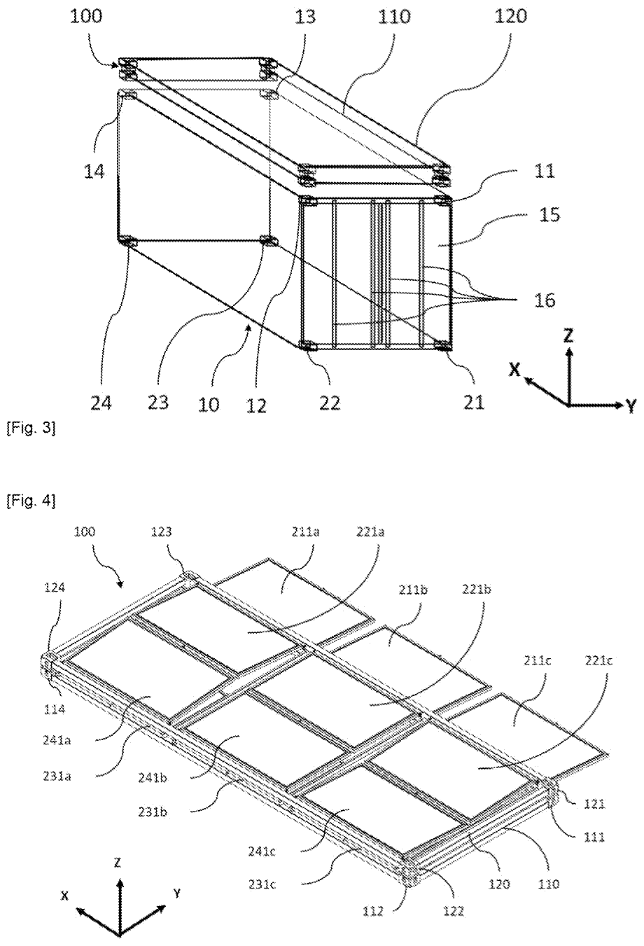

The simplified diagram of [FIG. 3] shows the container 10 of [FIG. 1] above which is arranged the framework 100 according to the embodiments. The framework 100 comprises a lower rectangular frame 110 and an upper rectangular frame 120, which are identical and stacked edge-to-edge, the second being above the first. As will appear from the detailed description of an embodiment of the framework 100, the frames 110 and 120 are welded together, while being spaced apart vertically from one another by spacers of determined height. Thus, the frames 110 and 120 form a substantially rectangular housing. In order to not weigh down the drawings with too many numerical references, sometimes in the description below, the housing is referred to by the pair of references 110, 120.

The lower frame 110 comprises four bottom corner parts and the upper frame 120 comprises four top corner parts, which are stacked two-by-two. Each of the lower and upper frames comprises two longitudinal beams and two transverse beams which are stacked two-by-two, and which each connect the four bottom corner parts and the four top corner parts, two-by-two, respectively. In other words, also, each of the lower 110 and upper 120 frames comprises a pair of longitudinal beams and a pair of transverse beams which are stacked two-by-two, and said pairs of beams each connect the four bottom corner parts and the four top corner parts, two-by-two, respectively.

The housing 110, 120 of the framework 100 can have dimensions in the plane XY, i.e. a length in the longitudinal direction X and a width in the transverse direction Y, which are substantially equal to the corresponding dimensions of the container 10 on which the framework must be able to be arranged. Thus, the framework 100 can rest on the container 10 and can also itself be fixed by way of the four corner parts of the lower frame 100, in cooperation with the four corner parts 11-14 of the top side of the container 10. Advantageously, this fixing can be achieved with conventional hooks, which are usually used for fixing ISO containers to one another, when they are stacked or attached.

In embodiments, the housing 110, 120 of the framework 100 can have a height in the vertical direction Z which is at most equal to one foot, i.e. to about 30 cm. In this manner, an ISO container 8.5 feet high, when it is equipped with a framework 100 according to the embodiments of the invention which is arranged above said container, has at most, the height of an ISO container 9.5 feet high, i.e. the height of a “high cube” (HC)-type container. This feature advantageously enables the transport of a unit formed from an ISO container 8.5 feet high, equipped with a framework according to the embodiments, under the same conditions as an HC-type ISO container, 9.5 feet high. In other words, an ISO container 8.5 feet high on which is arranged a framework according to the embodiments, has the standard dimensions of an ISO container of corresponding length and width, but 9.5 feet high, which is an advantage for the transport and storage by stacking, of the container thus equipped, which thus has the standard dimensions of a known HC-type ISO container.

A first embodiment of a framework according to the invention will now be described in more detail, in reference to the diagram of [FIG. 4]. In this figure, the framework 100 is oriented in the space like that of [FIG. 1], above the container 10 shown in [FIG. 1] and not represented again in [FIG. 4].

By considering the standpoint of an observer who would be positioned facing the front side 15 of the container 10 of [FIG. 1], the framework 100 of [FIG. 4] comprises, on the right-hand half (with respect to a median of the framework 110, 120) that extends in the longitudinal direction X, a row of lower solar panels comprising, in the example shown, three lower solar panels 211a, 211b and 211c, as well as a row of upper solar panels comprising, in the example shown, three solar panels 221a, 221b and 221c. The framework 100 also comprises, on the left-hand half, another row of lower solar panels 231a, 231b and 231c and another row of upper solar panels 241a, 241b and 241c, identical to the row of lower panels 211a-211c and to the row of upper panels 221a-221c, respectively. In other words, in the embodiment represented, the framework 100 comprises twelve solar panels, at a rate of four rows each having three adjacent solar panels two-by-two in the longitudinal direction X. Each of the solar panels is arranged on an associated movable frame (which will be described in detail below). Thus, the solar panel is movable between the non-deployed position, on the one hand, and a fully deployed position, on the other hand.

In the first embodiment considered in this case and represented in the figures of the drawings, the rows of adjacent lower solar panels 211a-211c and 231a-231c two-by-two, as well as the rows of adjacent upper solar panels 221a-221c and 241a-241c two-by-two that extend in the longitudinal direction X of the framework 100. Naturally, however, a person skilled in the art will assess that in other embodiments, all or some of these rows of solar panels can extend in the transverse direction Y instead of the longitudinal direction X. This choice can depend, in particular, on the dimensions of the solar panels used, on the total number of solar panels to be used, and on considerations specific to any application of the principle of the invention.

In the fully deployed position of the solar panels of the rows of lower panels, the surface area offered by the assembly of all these photovoltaic panels is, thus, substantially double the upper surface area of the container 10 and of the framework 100 (about twelve times the surface area of such a panel, instead of six times this surface area). A person skilled in the art will assess that the maximum number of solar panels comprised in each of these rows can vary, and only depends on the dimensions of a solar panel in the longitudinal direction X, as well as the length of the container 10 (and therefore of the framework 100) in this longitudinal direction X.

Each of the solar panels is mounted on an associated movable frame (which will be described in detail below), which belongs to the framework 100, so as to be deployable. In other words, the solar panels thus mounted, each on an associated movable frame, are made movable between a non-deployed position, on the one hand, and a fully deployed position, on the other hand. The non-deployed position enables the storage and the transport of the framework by itself or arranged on an ISO container of corresponding dimensions. The deployed position enables the operational functioning, wherein the panels generate electricity from solar energy.

In the example shown in [FIG. 4], the lower solar panels 211a, 211b and 211c (below conventionally referenced 211a-211c) are in the deployed position. In this deployed position, the movable frames associated with the lower solar panels 211a-211c (laterally extend outwards from the framework 100, i.e. beyond the lateral dimensions of the rectangle formed by the housing of the framework 100). As will appear in more detail, in a detailed description which will be given below, the lower solar panels 211a-211c thus extend between the respective right-hand longitudinal beams, which are stacked and spaced apart for this purpose, from the lower frame 110 and from the upper frame 120 of the housing of the framework 100. The upper solar panels 221a-221c, regarding them, can be inclined with respect to the horizontal of an angle of between 0 and 90°, usually between 3 and 10°, for example of an angle substantially equal to about 5° as shown for the solar panel 221a and the solar panel 241a, by pivoting around an articulation provided at the left-hand longitudinal beam of the upper frame 120. They can be maintained in this position thanks to struts which can be positioned, or jacks, or preferably thanks to mutual blocking means which will be described below. A person skilled in the art will observe that, thanks to a gap between the beams and ad hoc restraining means, the lower solar panels 211a-211c and 231a-231c can also have, in their fully deployed position, an inclination with respect to the horizontal substantially of the same angle that the upper solar panels 221a-221c or 241a-241c, by the effect of gravity.

The value of the tilt angle of the solar panels indicated in the paragraph above is only indicative. It is not limiting. Such a tilt angle value of the solar panels can make it possible to improve the capturing of solar energy, according to the latitude of the place of use. In reality, however, the impact of this inclination is not very significant in most regions in the world where the use of the framework can be considered. But, the usual inclination of the solar panels of an angle of between 3 and 10° with respect to the horizontal is however advantageous, as it enables a natural washing of the solar panels by runoff of rainwater, which makes it possible to remove dirt (sand, dust, etc.), as well as tree leaves if necessary, which can be deposited on the solar panels on the site of use of the framework 100.

A person skilled in the art will also assess that an inclination of the solar panels in the fully deployed position is an advantageous feature for the abovementioned reasons, but is not an essential feature from the operational standpoint. Embodiments can provide that the photovoltaic panels remain flat, in the horizontal plane XY, in the fully deployed position. The average incidence of the sun rays during a complete day with respect to the plane of the solar panels does not, indeed, have a great impact on the capturing of solar energy for a use at the latitudes considered.

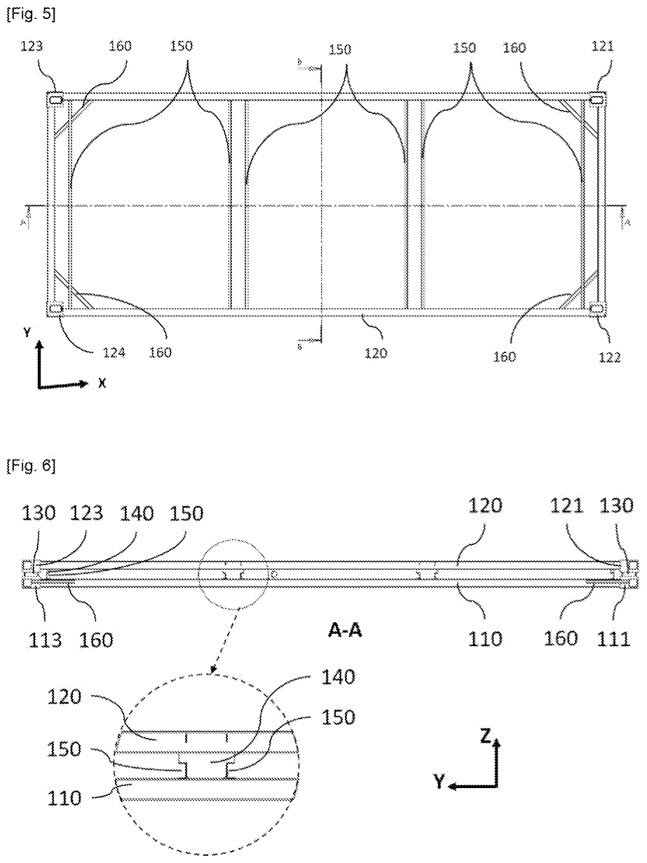

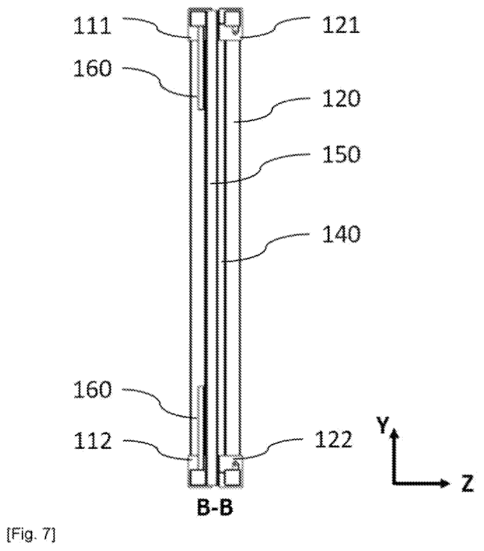

A detailed embodiment of the housing 110, 120 of the framework 100 of [FIG. 4] will now be described, in reference to FIGS. 5 to 8, suitable for being equipped with twelve solar panels. [FIG. 5] shows a top view of the housing. [FIG. 6] and [FIG. 7], are side views along the cross-section A-A and along the cross-section B-B, respectively, of [FIG. 5]. The housing 110, 120 forms a one-piece assembly obtained by the assembly of steel parts welded together.

First, in reference to FIGS. 4 and 5, the lower frame 110 of the housing comprises four corner parts 111, 112, 113 and 114, identical to the corner parts 1, 2, 3 and 4 of [FIG. 2], respectively (in fact, the corner part 113 cannot be seen in FIGS. 4 and 5, and is located below the corner part 123 of the upper frame 120, see below). It is reminded that these corner parts are cast parts obtained by steel moulding, and compliant with the specifications of the standard ISO 1161-1984. These corners 111, 112, 113 and 114 are connected two-by-two by two longitudinal beams and two transverse beams of the frame 110, for example square-section steel tubular beams. In the same manner, the upper frame 120 of the housing comprises four corner parts 121, 122, 123 and 124, identical to the corner parts 1, 2, 3 and 4 of [FIG. 2], respectively. These corners 121, 122, 123 and 124 are connected two-by-two by two longitudinal beams and two transverse beams of the upper frame 120 identical to the abovementioned beams of the lower frame 110. The lower frame 110 and the upper frame 120 are of identical dimensions and are stacked edge-to-edge, i.e. that their respective corner parts are stacked two-by-two in the same manner as their respective longitudinal beams and their respective transverse beams. In other words, the corners 121, 122, 123 and 124 of the upper frame 120 come to the right of the corners 111, 112, 113 and 114, respectively, of the lower frame 110.

As can be seen, in particular, in [FIG. 6] for the corners 111 and 121 of the front-right corner of the housing 110, 120 and for the corners 112 and 122 of the front-left corner of the housing 110, 120, the lower frame 110 and the upper frame 120 are spaced apart in the vertical direction Z, by spacers 130 that extend vertically between the respective longitudinal beams of said frames 110 and 120. The spacers 130 are, for example, produced with the rectangular-section steel tube. These spacers also having the function of facilitating the assembly by welding together of the corners 111 and 121, 112 and 122, 113 and 123, as well as 114 and 124.

By again considering the diagram of [FIG. 5], the housing 110, 120 also comprises transverse slides 150, made, for example, with the folded sheet, or UPN-type steel beams which are welded by their lower side directly to the two longitudinal beams of the lower frame 110, and which are welded by their upper side indirectly to the two longitudinal beams of the upper frame 120 by way of transverse stringers 140, as shown on the detail D of [FIG. 6]. In other words, the transverse slides 150 are surmounted by transverse stringers 140 which ensure its reinforcement and complete the connection, in the vertical direction Z, thus formed between the pairs of longitudinal beams of the lower frame 110 and of the upper frame 120, respectively, of the housing of the framework 100. Furthermore, the transverse stringers 140 offer a support for movable frames respectively associated with the upper solar panels 221a-221c and 241a-241c, which rest on said transverse stringers 140 by the top, substantially in the plane of the upper frame 120, as well as will be explained below in reference to FIGS. 8, 9 and 10.

In the embodiment shown in FIGS. 5 and 6, the housing 110, 120 comprises six transverse slides 150, at a rate of three pairs of such slides mutually facing one another in the longitudinal direction X of the framework 100 by their respective open side. These three pairs of transverse slides 150 are adjacent two-by-two in the longitudinal direction X of the framework 100, by being distributed so as to share the rectangular surface of the framework 100 in the horizontal plane XY of the lower frame 110, in three rectangular zones, each having the same dimensions. In the example represented in the figures, the three pairs of transverse slides 150 (with two slides which are respectively adjacent to the two transverse beams of the lower frame 110) form three adjacent rectangular zones two-by-two in the longitudinal direction X.

In an embodiment, the housing 110, 120 comprises arms 160 respectively arranged at each of the corners of the lower frame 110, which are welded to the longitudinal beam and to the transverse beam forming said corner, so as to form a right angle with them. Although more than a reinforcement function of the housing, this right angle ensures a support function for the two transverse slides 150 (and their associated spacer 140) which are adjacent to the two transverse beams of the lower frame 110, so as to prevent the buckling of these elements. To this end, the arms 160 are arranged, in the vertical direction Z, just below said transverse slides 150.

The main function of the transverse slides 150 is indeed to form slides which extend in the transverse direction Y, and which are suitable and arranged by facing one another two-by-two in the longitudinal direction X, to enable the sliding in the transverse direction Y of the lower solar panels 211a, 211b and 211c, which are each arranged, to this end, in a respective movable frame (these movable frames will be described below in reference to the diagrams of FIGS. 8, 9 and 10).

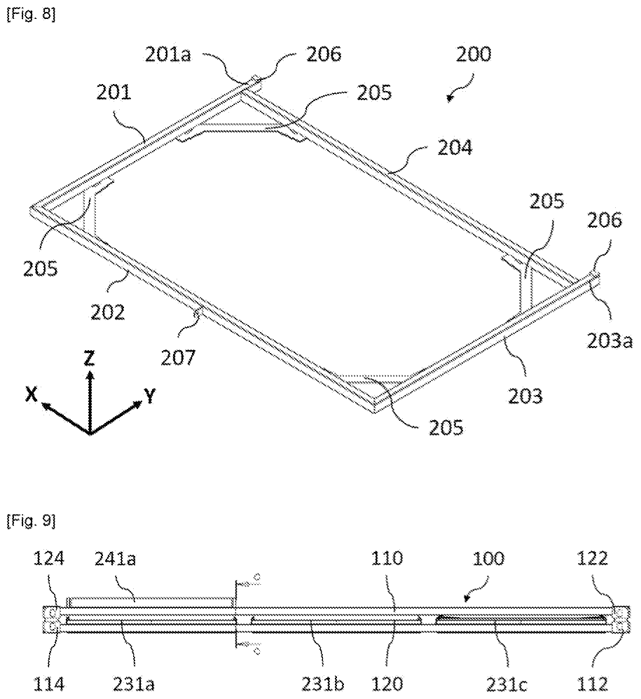

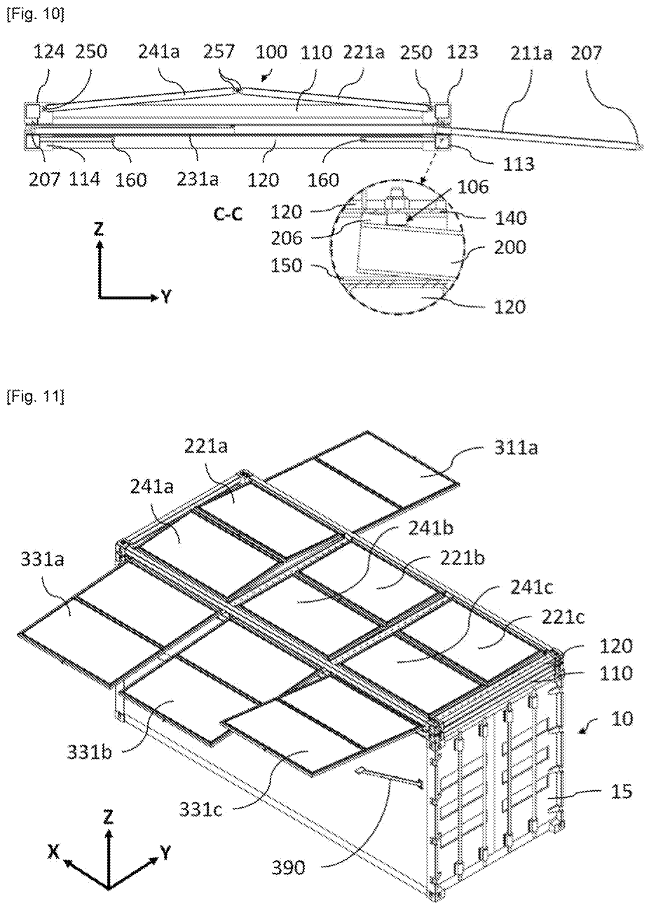

The movable parts of the framework 100 will now be described, in reference to [FIG. 8], to [FIG. 9] and to [FIG. 10]. It will be assessed that these movable parts are movable with respect to the housing 110, 120, in order to confer the deployable character to the solar panels. More specifically, the figures show an embodiment of a lower movable frame, associated with one of the right-hand lower solar panels 211a-211c, or to one of the left-hand lower solar panels 231a-231c, shown in [FIG. 4]. In an embodiment, the movable frames are all identical to one another.

Each solar panel is fixedly mounted in a movable frame, like the frame 200 shown in [FIG. 8], for example an aluminium or steel frame, said frame being movably mounted in the housing 110, 120 of the framework 100, as well as will be explained below. The lower movable frame 200 of [FIG. 8] is oriented in the figure as one of the lower movable frames associated with the left-hand lower solar panels 231a-231c in the representation of [FIG. 4].

In an embodiment, the lower movable frames, like the frame 200 of [FIG. 8], are rectangular-shaped, of dimensions in the plane XY which are slightly greater than the corresponding dimensions of the solar panels used. They can be made of rectangular-section tubular profiles. The frame 200 thus comprises two transverse uprights 201 and 203 that extend in the transverse direction Y of the housing 100 when the frame 200 is mounted in said framework, as well as two longitudinal uprights 202 and 204 that extend in the longitudinal direction X of the framework 100 when the frame 200 is mounted in said framework. On one side (at the top-left of [FIG. 8]), the transverse uprights 201 and 203 extend beyond the longitudinal upright 204 which connects them, so as to be extended outwards from the frame, i.e. beyond the transverse limits of the frame 200. Parts 201a and 203a for extending the transverse uprights 201 and 203, respectively, which correspond to this transverse extension beyond the longitudinal upright 204, each carry a restraining wedge 206, suitable for cooperating with an abutment 106 of the housing 110, 120 as well as it is shown in the detailed view of [FIG. 10]. These means 106, 206 have the function of restraining the movable frame 200 such that it does not escape fully from the housing 110, 120 in the fully deployed position of the associated solar panel.

The lower movable frame 200 further comprises a lug 207 fixed, for example by welding, to the middle (often the longitudinal direction X) of the longitudinal upright 202 opposite the longitudinal upright 204 which is on the side of the extensions 201a and 203a of the transverse uprights 201 and 203, respectively. This lug 207 enables an operator to catch the lower movable frame 200 to make it slide outwards from the housing 110, 120, in order to deploy the associated solar panel.

Finally, the lower movable frame 200 comprises four support lugs 205 that extend horizontally (i.e. in the plane XY) inside the frame, at each of the four corners of said frame, respectively. Each of said support lugs connects, by welding or by screwed assembly or other, one of the longitudinal uprights 202 and 204, on the one hand, and one of the transverse uprights 201 and 203, on the other hand, in the manner of a right angle. These supports have the function of rigidifying the movable frame 200, but also and particularly to support the associated solar panel (not represented in [FIG. 8]). The length in the direction X and the width in the direction Y of the movable frame 200 are suitable for receiving solar panels on the market, if necessary maintained by wedges, or by any other equivalent means like clamping flanges (not represented), for example, “clip”-type elastic flanges.

Solar panels on the market, available on the filing date of the present application, for example have the following dimensions (length×width×height):
panels of the Photowatt™ brand: 1675 mm×992 mm×35 mm;
solar panels of the Voltec™ brand: 1660 mm×998 mm×42 mm;
solar panels of the Rec™ brand: 1675 mm×997 mm×38 mm;
panels of the LG™ brand: 1700 mm×1016 mm×40 mm.

That is why, in an embodiment, a movable frame such as the frame 200 of [FIG. 8] can have a length equal to 1680 mm between its inner edges which are opposite one another, in order to be able to receive a solar panel, for example of any one of the three first models listed above, said panel thus being fixedly maintained in said movable frame using suitable wedges. Another embodiment of the frame 200 can have a length equal to 1705 mm between its inner edges opposite one another, in order to be able to receive a solar panel of the LG™ brand above.

[FIG. 9] is a side view of the framework 100 of [FIG. 4], with the fixed housing 110, 120 equipped with movable frames respectively associated with the lower solar panels 211a-211c and 231a-231c, as well as movable frames respectively associated with the upper solar panels 221a-221c and 241a-241c. [FIG. 10] is a cross-sectional view of the framework of [FIG. 9], in the cross-sectional plane C-C of said figure. These figures show the movable frame associated with the upper solar panel 241a for the fully deployed position of said associated solar panel, while the movable frames respectively associated with the upper solar panels 241b and 241c cannot be seen in this view, as said associated solar panels are in the non-deployed position, therefore the movable frames and their associated solar panels are fully housed in the plane of the upper frame 120 of the housing 110, 120. Likewise, each of the lower movable frames which can be seen in the view of [FIG. 9] is fully housed in the lower volume of the housing 110, 120 mainly in a horizontal plane comprised between that of the lower frame 110 and that of the upper frame 120 of said housing, given that the associated solar panels 231a, 231b and 231c are in the fully non-deployed position.

A person skilled in the art will assess that, during the deployment of the lower solar panels, like the lower solar panel 211a shown in [FIG. 10], each lower solar panel and its associated lower movable frame extends outwards from the housing of the framework 100 beyond the transverse limits of said housing, in the transverse direction Y (i.e. orthogonally to the plane of [FIG. 11]), between the respective longitudinal beams of the lower frame 110 and of the upper frame 120 of said housing, which are stacked in the vertical direction Z. The lower movable frames are slidingly guided by the slides 150 which can be best seen in [FIG. 6], i.e. that said slides 150 have the effect of slides to maintain them substantially aligned in the transverse direction Y.

A person skilled in the art will assess that the spacing along the vertical Z between the respective longitudinal beams of the lower frame 110 and of the upper frame 120 of the housing of the framework is greater than the height of the lower movable frames, each equipped with their associated solar panel 211a, 211b and 211c, such that each of said lower movable frames can slide in the slide 150 outwards from the housing with the capacity to incline at the least at the end of travel, downwards with respect to the main axis of said slide 150 (i.e. with respect to the transverse axis Y in the embodiment represented). In fact, this inclination occurs by the simple effect of gravity applied to the lower movable frames associated with the lower solar panels 211a, 211b and 211c, as soon as the centre of gravity exceeds, outwards from the limits of the housing of the framework, the limit formed by the longitudinal beams of the frames 110 and 120, respectively, of said housing. Thus, in the fully deployed position of the associated solar panel, said panel has a determined second slope, with respect to the plane of the framework, downwards.

By fixing at a determined distance, the clearance in the vertical Z between the respective longitudinal beams of the frames 110 and 120 of the housing of the framework 100 with respect to the height of the lower movable frames equipped with their associated solar panels 211a, 211b and 211c, it can be ensured that the tilt angle of said lower frames is about 3 to 10°, for example. In other words, the slope of the lower movable frames associated with the lower solar panels 211a, 211b and 211c in the fully deployed position can be substantially equal to the slope of the upper movable frames associated with the lower solar panels 221a, 221b and 221c in the deployed position, as shown in [FIG. 4] described above and can also best be seen in [FIG. 10] for the frames 211a and 221a. It is reminded that a slope of about 5° makes it possible to ensure a natural washing of the solar panels in the deployed position, thanks to rainwater. This slope also enables the cleaning with waterjet and squeegee, if necessary, by an operator standing upright around the modular construction element 10 which is equipped with the framework 100.

As already mentioned above, and as illustrated by the details of [FIG. 10], the lower movable frames comprise at least one restraining wedge 206 suitable for restraining the movable frame, such that it does not fully escape the housing in the fully deployed position of the associated solar panel. This wedge can be a plate with the dimensions, in the longitudinal direction X, of the upper face of the transverse uprights 201 and 203 of the lower movable frame 200. In an example, the wedge 206 is welded onto the top of said upright. Thus, it can abut against the abutment 106 which is maintained on the lower face of the corresponding longitudinal beam of the upper frame 120 of the housing of the framework 100 and/or of the slide 150 and/or of the spacer 140, in the fully deployed position of the associated solar panel. A person skilled in the art will assess that the invention is not intended to be limited by the embodiment of the wedges and abutments of the movable frames, and plenty of other embodiments in its scope can be considered to achieve this restraining function of the movable frames, such that they do not fully escape from the housing 110, 120 in the fully deployed position of the associated solar panels.

Whatever the embodiment of the abutments, in the deployed position of the solar panels, the movable frames associated with the lower solar panels 211a, 211b and 211c on the one hand, and the movable frames associated with the upper solar panels 221a, 221b and 221c on the other hand, are substantially in the same plan, by being adjacent two-by-two in the transverse direction Y, with the lower movable frames which extend totally or partially outwards beyond the transverse limits of the housing, passing between the respective stacked beams of the lower frame 110 and of the upper frame 120 of said housing. In other words, the total surface area of the solar panels can be substantially double the surface area of the framework in the horizontal plane XY, and therefore double the surface area of the roof of the container 10 which is equipped with such a framework.

Now relating to the upper movable frames associated with the upper panels 221a-221c and 241a-241c, a person skilled in the art will assess that they are substantially the same structure and the same dimensions as the lower movable frame 200 represented in [FIG. 8]. However, and as shown in [FIG. 10], they have no restraining wedges, like the restraining wedges 206 of the movable frame 200 of [FIG. 8] arranged at the extensions of the transverse uprights 201 and 203. Conversely, they are equipped with hinge elements 250 cooperating with complementary hinge elements fixed, for example, by welding, on the corresponding longitudinal beam of the upper frame 120 of the housing 110, 120. Thanks to these hinge elements, the upper movable frames associated with the upper solar panels can pivot, between the non-deployed position and the deployed position of said solar panels.

In the fully deployed position of the upper solar panels, the pairs of associated movable frames which are located adjacently on either side, i.e. to the left and to the right, of the grand median (median along the longitudinal axis X) of the rectangle formed by the upper frame 120 of the housing 110, 120, can be maintained together by lugs 257 identical to the lug 207 of the lower movable frame 200 of [FIG. 8]. This connection can be obtained, for example, using a pin, a shackle assembly, a snap hook, a bolt, etc., cooperating with ad hoc holes in the lugs 257. These different elements form mutual blocking means, suitable for maintaining the two upper movable frames together in the deployed position of the associated solar panels. In this position, each of the upper movable frames is in the inclined position with a slope of determined value with respect to the plane XY of the framework, namely from 3 to 10° in the example, downwards in the direction of the outside, i.e. beyond the transverse limits of the housing 110, 120, between an imaginary ridge line and the longitudinal beams opposite the upper frame 120 of said housing. One or more struts can also be provided to maintain in the thus inclined position, the pairs of upper movable frames which are secured together by said mutual blocking means. For example, the struts can also be fixed using the pin or the abovementioned equivalent means, which passes through the holes provided in the lugs.

Naturally, if the rows of upper solar panels 221a-221c and 241a-241c extend in the transverse direction Y (instead of the longitudinal direction X), the hinges are arranged at a transverse beam of the upper frame 120 of the housing 110, 120 of the framework 100 (instead of a longitudinal beam), such that the corresponding movable frame can be inclined downwards in the direction of the outside, i.e. beyond the longitudinal limits of the housing (instead of its transverse limits).

In reference to the diagram of [FIG. 11], a second embodiment of a framework according to the invention will now be described, which makes it possible to increase by 50%, the capacity to produce photovoltaic energy with respect to the first embodiment presented so far in reference in particular to the diagram of [FIG. 4]. Indeed, in this second embodiment, the framework 100 can comprise up to eighteen solar panels instead of twelve solar panels for the framework of [FIG. 4]. In [FIG. 11], the framework 100 is oriented in the space like that of [FIG. 1] and of [FIG. 4], above the container 10 shown in [FIG. 1] and already described in reference to said figure. The elements common to the two embodiments, of FIGS. 4 and 11 respectively, and which have already been described above in reference to the first embodiment, will not be described again in this case.

By considering the standpoint of an observer who would be positioned facing the front side 15 of the container 10, the framework 100 of [FIG. 4] comprises, at the right-hand half (with respect to a median of the framework 110, 120) that extends in the longitudinal direction X, a row of lower solar panels comprising, in the example shown, three pairs of lower solar panels 311a, 311b and 311c, as well as a row of upper solar panels comprising, in the example shown, the three upper solar panels 221a, 221b and 221c already described in reference to the first embodiment. A person skilled in the art will assess that the lower solar panel 311a can be seen in the figure, as it is in the deployed position, while the lower solar panels 311b and 311c cannot be seen, as they are in the non-deployed position, therefore housed inside the volume of the framework 100. The framework 100 also comprises, at the left-hand half, another row of lower solar panels 331a, 331b and 331c and the row of upper solar panels 241a, 241b and 241c already described in reference to the first embodiment.

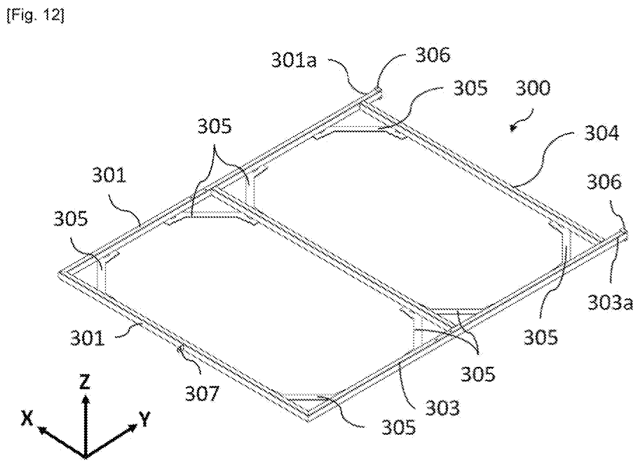

In other words, in the embodiment represented, the framework 100 comprises eighteen solar panels, at a rate of four rows, two of which each having three adjacent solar panels two-to-two in the longitudinal direction X, and two of which each having three pairs of adjacent solar panels two-by-two in the longitudinal direction X. Each of the solar panels is arranged on an associated movable frame. For the movable frames associated with the lower solar panels, this is the movable frame which has been described above, mainly in reference to [FIG. 10], by reference further to [FIG. 8] which shows a movable frame associated with the lower solar panels according to the first embodiment. For the movable frames associated with the lower solar panels of the second embodiment described in this case, this is a movable frame 300 which will be described below in reference to [FIG. 12].

In the second embodiment considered in this case, and represented in the figures of the drawings, the row of adjacent lower solar panels 311a-311c and 331a-331c two-by-two, as well as the rows of adjacent upper solar panels 221a-221c and 241a-241c two-by-two extend in the longitudinal direction X of the framework 100. Naturally, however, a person skilled in the art will assess that in other embodiments, all or some of these rows of solar panels can extend in the transverse direction Y instead of the longitudinal direction X.

In the fully deployed position of the solar panels of the rows of lower panels, the surface area offered by the assembly of all the photovoltaic panels is, thus, substantially triple the upper surface area of the container 10 and of the framework 100 (about eighteen times the surface area of such a panel, instead of six times this surface area). Uke for the first embodiment, a person skilled in the art will assess that the maximum number of solar panels comprised in each of these rows can vary, and only depends on the dimensions of a solar panel in the longitudinal direction X, as well as the length of the container 10 (and therefore of the framework 100) in this longitudinal direction X.

[FIG. 12] shows an embodiment of a lower movable frame 300, associated with a pair of lower solar panels, like the pairs 311a-311c and the pairs 331a-331c of [FIG. 11]. The lower movable frame 300 is oriented to [FIG. 12] like one of the lower movable frames associated with the pairs of left-hand lower solar panels 331a-331c in the representation of [FIG. 11].

The lower movable frame 300 is very similar to the lower movable frame 200 of [FIG. 8]. It thus has:
two transverse uprights 301 and 303 identical to the transverse uprights 201 and 203 of the frame 200, but of length along the transverse axis Y substantially equal to double the length of said uprights 201 and 203. The uprights 301 and 303 are extended by extensions 301a and 303a, respectively, identical to the extensions 201a and 203a of the uprights 201 and 203, respectively, and are each provided, like the latter, with a restraining wedge 306 identical to the restraining wedge 206 of the frame 200;
a first longitudinal upright of transverse end 304, which corresponds and which is identical to the longitudinal upright 204 of the frame 200, as well as a second longitudinal upright of transverse end 302, which corresponds and which is identical to the longitudinal upright 202 of the frame 200, further as well as a central longitudinal upright 306 identical to the upright 304 and located at an equal distance, in the transverse direction Y, between said first and second transverse end uprights 304 and 302;
eight support lugs 305 identical to the support lugs 205 of the frame 200, inside the frame 300, at each of the eight inner corners of said frame 300, respectively. Each of said support lugs connects, by welding or by screwed assembly or other, one of the longitudinal uprights 302, 306 and 204, on the one hand, and one of the transverse uprights 301 and 303, on the other hand, in the manner of a right angle; and,
a lug 307 identical to the lug 207 of the frame 200 fixed, for example by welding, to the middle (in the longitudinal direction X) of the second longitudinal end upright 302.

Each of the two solar panels of a pair of lower solar panels 311a-311c and 331a-331c is fixedly mounted in a movable frame, like the frame 300 shown in [FIG. 10], in respective adjacent positions in the transverse direction Y, on either side of the central longitudinal upright 306. In other words, a movable frame like the movable frame 300 of [FIG. 12] is suitable for receiving a pair of adjacent lower solar panels, in the transverse direction Y.

As a person skilled in the art will have understood, the transverse dimension of the frame 300 associated with a pair of lower solar panels from among the pairs 311a-311c and the pairs 331a-331c, corresponds substantially to the transverse dimension (i.e. to the width) of the framework 100 and therefore of the container 10 equipped with said framework. That is why the housing 110, 120 used in the second embodiment of the framework 100 considered in this case, has slight differences with respect to that used in the first embodiment and represented in FIGS. 5, 6, 7, 9 and 10.

At a top view, the housing 110, 120 of the second embodiment of the framework 100 seems identical to the housing 110, 120 of the first embodiment of said framework, such as represented in [FIG. 5]. That is why a top view of the housing 110, 120 according to the second embodiment of the framework is not specifically given in the drawings. A person skilled in the art can refer to [FIG. 5] for that. However, the design of the housing is substantially different, relating to the slides for the lower movable frames.

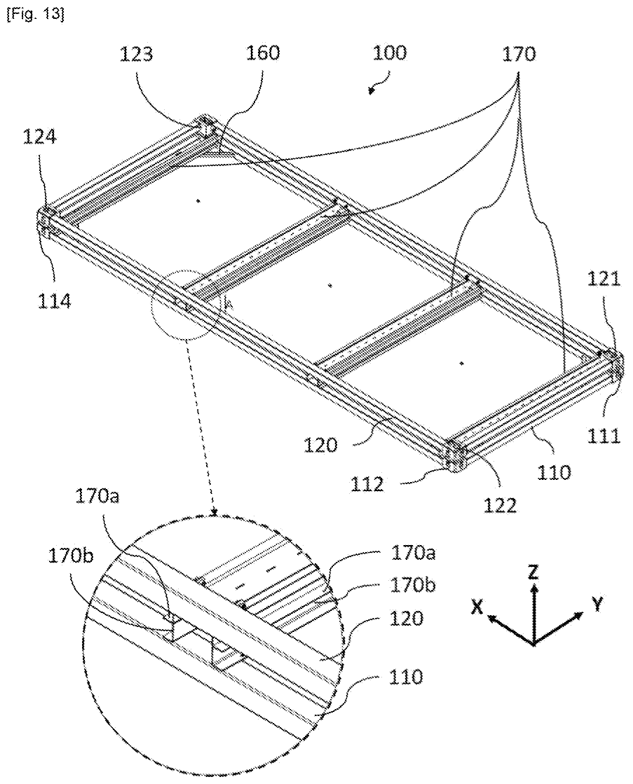

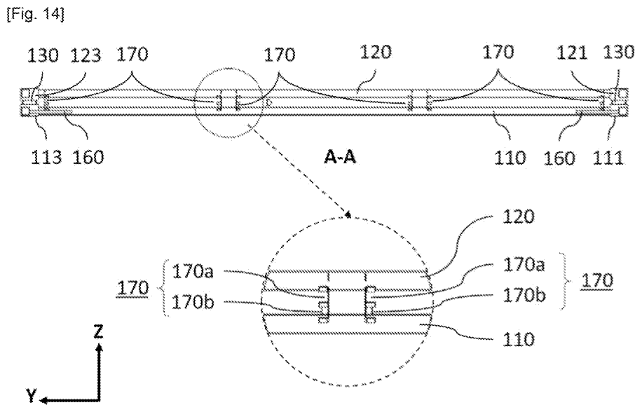

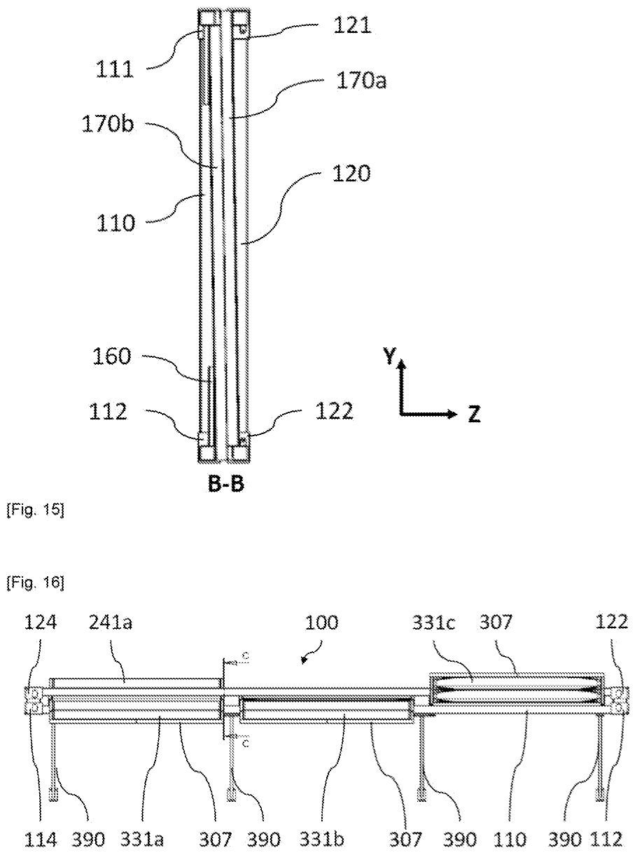

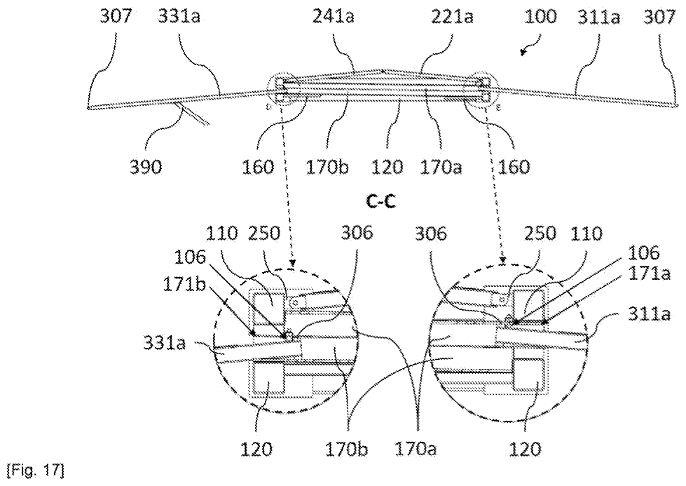

This will be summarised in reference to [FIG. 13] and to [FIG. 14] and to [FIG. 15]. [FIG. 13] is a three-dimensional view of the housing 110, 120 alone, i.e. without the movable frames. [FIG. 14] and [FIG. 15] are a front, cross-sectional view along the cross-section A-A of [FIG. 5] and a side, cross-sectional view along the cross-section B-B of said [FIG. 5], and therefore correspond to [FIG. 6] and [FIG. 7], respectively, of the first embodiment already described. The second embodiment of the framework 100 is further illustrated by [FIG. 16] and [FIG. 17], which are a front view showing the left-hand lateral side of the framework 100 according to the second embodiment with the housing 110, 120 of [FIG. 13] equipped with movable frames for the lower and upper solar panels shown in [FIG. 12], and a cross-sectional view of the framework 100 of [FIG. 16] along the cross-section C-C of said figure. In order to not extend the description for no reason, only the difference between the second embodiment and the first embodiment are described in this case.

Mainly, the slides 150 of the housing 110, 120 according to the first embodiment of the framework 100 according to FIGS. 6 and 7 are replaced in the housing 110, 120 according to the second embodiment of the framework 100 according to FIGS. 13 to 17 by double slides 170. By “double slides”, this means slides 170 which have two stacked slides 170a and 170b, as shown in particular on the detailed view D of [FIG. 13], and on the details D and E of [FIG. 17]. Such double slides can be made with two stacked UPN-type beams, having an overall, cross-sectional profile, which has the shape of the letter “E”. In a variant, this can be one single “U”-shaped section part with a flat iron welded between the two flats of the “U”, to make the shape of an “E”.

Furthermore, as shown in FIGS. 13 and 14, all the double slides 170 are parallel to one another, but they are not precisely in the horizontal plane XY, as well as can be seen, in particular, in FIGS. 14 and 15 and on the details D and E of [FIG. 17]. On the contrary, each of the slides 107a and 170b is inclined downwards, from the left to the right, by adopting the standpoint of an observer who would be standing in front of the double doors 15 of the container 10 equipped with the framework 100 as already summarised in reference to [FIG. 1].

To this end, in particular, the arms 160 of the housing 110, 120 which ensure a support function for the two transverse slides 150 (and their associated spacer 140) which are adjacent to the two transverse beams of the lower frame 110, are not at the same height, i.e. not at the same level along the vertical axis Z. Indeed, the arms 160 which are arranged at each of the corners of the lower frame 110 on the right side of the housing (i.e. on the side of the corner parts 111, 121 and 113, 123), are in the position lower than the arms 160 of the housing which are arranged at each of the corners of the lower frame 110 on the left side of said housing (i.e. on the side of the corner parts 112, 122 and 114, 124). Mainly, the two arms 160 located on the right side of the housing 110, 120 extend from the level of the upper faces of the longitudinal beam and of each of the transverse beams, respectively, of the lower frame 110, while the two arms 160 located on the left side of the housing 110, 120 extend from the level of the lower faces of the longitudinal beam and of each of the transverse beams, respectively, of said lower frame 110. This can be seen, in particular, in [FIG. 15] and in [FIG. 17].

Finally, a person skilled in the art will assess that the restraining wedges 306 which are mounted at the ends of the lower movable frames in order to restrain them when they are in the fully deployed position of the associated lower solar panels, always each cooperate (i.e. like in the first embodiment of the framework) with an abutment 106, as summarised above regarding the first embodiment. However, and as shown in the detailed views D and E of [FIG. 17] for the left side and for the right side, respectively, of the framework 100, the abutment 106 is arranged on the upper edge 171a of the upper slide 170a of the right side (see detail E), i.e. also on the “top bar” of the “E” of the section of the beam constituting the slide 170, while it is arranged on the upper edge 171b of the lower slide 170b of the left side (see detail D), i.e. also on the “middle bar” of the “E” of the section of the beam constituting said slide 170.

As regards the upper movable supports, associated with the upper solar panels 221a-221c and 241a-241c, the second embodiment is identical to the first embodiment. The figures and, in particular, the detailed views D and E of [FIG. 17] show the hinges 250 which enable the deployment of these upper solar panels, which are arranged on the longitudinal beams of the upper frame 110.

To finish, and as shown in FIGS. 11 and 16, the framework 100 according to the second embodiment can be completed by suspension struts 390, for example removable suspension struts, which can be fixed by any means suitable for the lower movable frames in the fully deployed position of the associated solar panels, on the one hand, and the large walls of the container, which is equipped with the framework 100, on the other hand. These means make it possible to maintain in position, the movable frames when they exit from the housing by no longer being restrained by their restraining wedges 306, and to rigidify the assembly formed of the movable frames and the container and the framework, in order to alleviate the forces and to avoid or to reduce the risk of deforming the movable frames by the effect of wind, for example. Such suspension struts can also be used with the first embodiment (with twelve solar panels, in the example), but they are particularly advantageous in the second embodiment (with eighteen solar panels, for example), given the larger cantilever of the movable frames in the fully deployed position of the associated solar panels.

Thus, a person skilled in the art will assess that, during the deployment of the lower movable frames associated with the lower solar panels, the movable frames associated with the lower solar panels on the right side 211a-211c slide (under the effect of a traction exerted by an operator) from the left to the right (i.e. from the inside of the housing in the direction of the outside of the housing, beyond the transverse limits of said housing) with a slight inclination from top to bottom. Conversely, during the deployment of the lower movable frames associated with the lower solar panels, the movable frames associated with the lower solar panels of the left side 231a-231c slide from the right to the left (i.e. from the inside of the housing in the direction of the outside of the housing, beyond the transverse limits of said housing) with a slight inclination from bottom to top. And, in this manner, each of the slides 170a and 170 of each double slide 170 opens out outwards from the housing 110, 120, at the corresponding longitudinal beam of said housing, precisely at the same height, between the frames 110 and 120. This can be seen in [FIG. 15] and [FIG. 17].

This arrangement of the double slides 170 with respect to the horizontal plane XY makes it possible to house, operationally, said double slides 170 (which however have a height substantially equal to double that of the “single” slides 150 of the first embodiment according to FIGS. 6 to 10), inside the same rectangular volume of the framework 100. In other words, the framework 100 according to the second embodiment presently described, although offering the possibility of having eighteen solar panels instead of twelve solar panels of the first embodiment, preserves the same bulk, and in particular, the same height substantially equal to 1 foot, i.e. 30 cm, with the technical advantages already mentioned.

The present invention has been described and illustrated in the present detailed description and in the figures of the accompanying drawings, in possible embodiments. The present invention is not limited, however, to the embodiments presented. Other variants and embodiments can be deduced and implemented by a person skilled in the art upon reading the present description and the accompanying drawings.

In particular, in the first (respectively second) embodiment shown in particular in [FIG. 4] (respectively in [FIG. 11]), the framework 100 comprises two rows of three lower movable frames (respectively pairs of frames), like the adjacent frames 211a, 211b and 211c (respectively 331a-331c) two-by-two in the longitudinal direction X of the lower frame 110 of the framework, at a rate of one row on either side, respectively, of a median of said lower frame of the framework that extends in said longitudinal direction X in the deployed position of the associated solar panels. The framework also comprises two rows of three upper movable frames, like the adjacent frames 221a, 221b and 221c two-by-two in the longitudinal direction of the upper frame 120 of the framework, at a rate of one row on either side, respectively, of a median of said upper frame of the framework that extends in said longitudinal direction. Naturally, the number of three lower movable frames and the number of adjacent movable frames in the longitudinal direction X of the lower frame 100 or of the upper frame 120, respectively, is only an example, which only depends on the length of the framework in the longitudinal direction X, which depends on the longitudinal length of the modular construction element on which the framework must be arranged. Embodiments can have only one or two adjacent movable frames in each row for smaller containers, or conversely, four such frames or more for larger containers.

Moreover, the rectangular shape of the framework 100 in the horizontal plane XY can be, in a particular embodiment, a square shape if the framework is suitable for being used with an 8-foot-long modular construction element, for example. In this regard, a square is only a particular case of a rectangle, i.e. it is a regular rectangle having four sides of an equal length.

Furthermore, in the embodiments described above, the lower movable frames extend transversally (in the direction Y) outwards from the housing 110, 120 between stacked longitudinal beams of the lower frame 110 and of the upper frame 120. However, it is obvious that, in other embodiments, all or some of the lower movable frames can extend longitudinally (in the direction X) outwards from the housing 110, 120 between stacked transverse beams of the lower frame 110 and of the upper frame 120. Also, these two embodiments can be combined. In other words, lower movable frames extend transversally outwards from the housing 110, 120 between stacked longitudinal beams of the lower frame 110 and of the upper frame 120, and/or other lower movable frames extend outwards from the housing 110, 120 longitudinally between stacked transverse beams of the lower frame 110 and of the upper frame 120.

Advantageously, the framework according to the embodiments which have been described can be lifted by any lifting and handling vehicles which are also provided to, and which suit, the lifting of containers. Such vehicles comprise, in particular: super-heavyweight forklifts and container stackers, self-propelled gantries for containers, container lifting beams, lifting cranes like harbour cranes or others, etc. The gripping by such lifting vehicles can be done at the corners of containers, by ISO means.

Also, frameworks according to the embodiments which have been described are stackable, i.e. that they can be stacked, i.e. piling them on top of one another. This facilitates the transport, handling and storage of the frameworks. Stacked frameworks rest one on the other via the container corners described, which respect the standard ISO 1161. More than six frameworks can be stacked, for example at least eight frameworks, while not exceeding the total weight of a loaded container.

Given the longitudinal, transverse and height dimensions of a framework such as those described above, eight such stacked frameworks can be contained in the volume of a 20-foot ISO container. This makes it possible to easily transport frameworks in the same manner as, and if necessary, with such containers, by sea, rail and/or road transport from a place of manufacture to a place of use, for example.

In the claims, the term “comprise” or “has” does not exclude other elements or other steps. One single processor or several other units can be used to implement the invention. The different features presented and/or claimed can be advantageously combined. Their presence in the description or in different dependent claims, do not exclude this possibility. The reference signs could not be understood as limiting the scope of the invention.

1-10. (canceled)

11. Framework for deployable solar panels that can be arranged above a container-type modular element, comprising a substantially rectangular housing, wherein:
the rectangular housing has a lower frame and an upper frame of substantially identical rectangular shapes, which are stacked edge-to-edge, while being spaced apart vertically from one another by spacers of a determined height;
the lower frame comprises four bottom corner parts and the upper frame comprising four top corner parts, which are stacked two-by-two;
each of the lower and upper frames comprises a pair of longitudinal beams and a pair of transverse beams which are stacked two-by-two, said pairs of beams each connecting two-by-two the four bottom corner parts and the four top corner parts, respectively:
the framework further comprises at least one first lower movable frame and at least one upper movable frame which are suitable for each receiving a deployable associated solar panel, and which are arranged such that they are in the non-deployed position of the associated solar panels, fully contained inside the rectangular housing in respective planes one above the other, and are in the deployed position of the associated solar panels, substantially in the same plane side by side with the lower movable frame which extends at least partially outwards beyond the transverse or longitudinal limits of the housing, passing between two respective stacked beams of the lower frame and of the upper frame of said housing, namely between a beam of one of the pairs of transverse beams of the lower frame and a beam of one of the pairs of transverse beams of the upper frame, or between a beam of one of the pairs of longitudinal beams of the lower frame and a beam of one of the pairs of longitudinal beams of the upper frame, respectively.

12. Framework according to claim 11, wherein the corner parts are container corner parts complying with the standard ISO 1161-1984.

13. Framework according to claim 11, wherein the overall height of the framework, in the non-deployed position of the lower movable frame and of the lower movable frame is at least equal to 1 foot, that is about 30 centimetres.

14. Framework according to claim 11, further comprising hinges arranged at a longitudinal beam or a transverse beam of the upper frame of the housing, coupling the upper movable frame to said upper frame of the housing, such that said upper movable frame can pivot around said hinges during the deployment of the associated solar panel in order to be inclined, with a first determined slope with respect to the plane of the framework, outwards beyond the transverse or longitudinal limits of the housing.

15. Framework according to claim 14, comprising mutual blocking means, suitable for maintaining together two upper movable frames in the deployed position of the associated solar panels, each in the inclined position with a slope of determined value.

16. Framework according to claim 11, further comprising slides that extend perpendicularly to the respective stacked beams of the lower frame and of the upper frame of the housing between which the first lower movable frame can extend outwards beyond the transverse or longitudinal limits of the housing, to slidingly guide said movable frame in the transverse direction (Y) or the longitudinal direction (X), respectively.

17. Framework according to claim 16, wherein the first lower movable frame and the slide are arranged such that said first lower frame can slide in the slide outwards from the housing with the capacity to incline, at least at the end of travel, downwards with respect to the longitudinal axis of said slide, so as to have a determined second slope, with respect to the plane of the framework, in the deployed position of the associated solar panel.

18. Framework according to claim 17, wherein the lower movable frame comprises at least one restraining wedge suitable for cooperating with an abutment of the housing to restrain the movable frame, such that it does not fully escape from the housing in the fully deployed position of the associated solar panel.

19. Framework according to claim 11, comprising two rows of adjacent lower movable frames two-by-two in the longitudinal direction (X) of the lower frame of the framework, at a rate of one row on either side, respectively, of a median of said lower frame of the framework that extends in said longitudinal direction, and two rows of adjacent upper movable frames two-by-two in the longitudinal direction of the upper frame of the framework, at a rate of one row on either side, respectively, of a median of said upper frame of the framework that extends along said longitudinal direction.

20. Framework according to claim 11, comprising:
Two rows of pairs of adjacent lower movable frames two-by-two in the longitudinal direction (X) of the lower frame of the framework, said pairs of movable frames being fully contained, in the non-deployed position of the associated solar panels, inside the rectangular housing in respective planes one above the other, and that extend, in the deployed position of the associated solar panels, at least partially outwards beyond the transverse or longitudinal limits of the housing, passing between respective stacked beams of the lower frame and of the upper frame of said housing, each on a respective transverse or longitudinal side of said housing; and
two rows of adjacent upper movable frames two-by-two in the longitudinal direction of the upper frame of the framework, at a rate of one row on either side, respectively, of a median of said upper frame of the framework that extends in said longitudinal direction.
